(19) United States
(12) Patent Application Publication
(10) Pub. No.: US 2024/0429288 A1
(43) Pub. Date: Dec. 26, 2024

(54) SEMICONDUCTOR DEVICE WITH HIGH VOLTAGE TERMINATION

(71) Applicant: Infineon Technologies Austria AG, Villach (AT)

(72) Inventors: Felix Simon Winterer, München (DE); Christian Schippel, Dresden (DE); Dirk Priefert, Moers (DE); Andrei Sidelnicov, Dresden (DE)

(21) Appl. No.: 18/750,465

(22) Filed: Jun. 21, 2024

(30) Foreign Application Priority Data
Jun. 22, 2023 (DE) 102023116441.4
May 28, 2024 (DE) 102024204969.7

(51) Int. Cl. H01L 29/40; H01L 23/522; H01L 23/528; H01L 23/532; H01L 27/06

(52) U.S. Cl. CPC H01L 29/404; H01L 23/5225; H01L 23/5283; H01L 23/5329; H01L 27/0629

(57) ABSTRACT

A high voltage semiconductor device includes a substrate having a background doping of a first conductivity type. The substrate includes doped shielding regions of a complementary second conductivity type formed along a first substrate surface. An insulator layer is formed on the first substrate surface. A semiconductor layer is formed on the insulator layer opposite the substrate. A first interlayer dielectric is formed on the semiconductor layer. A first metal layer including laterally separated first field plate elements is formed on first portions of the first interlayer dielectric in a high voltage termination region. A second interlayer dielectric is formed on the first metal layer and on second portions of the first interlayer dielectric between the first field plate elements.

### TECHNICAL FIELD

Examples of the present disclosure relate to a semiconductor device having active elements integrated in a high voltage termination between a high voltage domain and a low voltage domain. In particular, the present disclosure may relate to gate driver circuits with signal paths that exchange electric signals between a high voltage domain and a low voltage domain.

### BACKGROUND

HV (high-voltage) semiconductor devices in CMOS technology (complementary metal oxide semiconductors) form an interface between standard CMOS devices with input voltages up to 5V on the one hand and industrial or consumer circuits operating with signal voltage levels above 30V on the other. Applications for such HV semiconductor devices exist in all kinds of power conversion and electrical drives up to the kW range, e.g., in power converters, robotics and the automotive industry. Such HV semiconductor devices typically include a low voltage part as a low voltage domain and a HV part as a high voltage domain. In the low voltage part, most of the signal processing is done at low operating voltage. The HV part operates at higher voltage level and provides a signal interface for power semiconductors using higher voltage levels and/or having higher current driving and sinking capability. An example of such a HV semiconductor device is a gate driver circuit that allows a microcontroller or DSP (digital signal processor) to efficiently turn on and off power semiconductor switches. HV terminations separate two or more CMOS circuits in different voltage domains, whose potentials can differ by several 100V up to some 1000V. The lateral width of the HV termination depends on the required voltage breakdown capability between the voltage domains. The HV termination may include a field plate structure and often occupies a significant portion of the HV semiconductor device.

There is a constant need to improve area efficiency of HV semiconductor devices with little additional effort.

### SUMMARY

Where a field plate structure is made of a single metal layer, each individual field plate element forms a 3D structure with a lower part lining a gap in a field plate oxide and two upper parts, each covering a section of the surface of the field plate oxide directly adjacent to the gap. A thickness of the metal layer is selected thin enough to allow high wiring density across the semiconductor device and thick enough to provide sufficiently stable wire bond pads. Typically, a deposition process using a high-density plasma is used to deposit a passivation layer on the lower part and the upper parts of the field plate elements and on portions of the field plate oxide between the field plate elements. The passivation layer is deposited with approximately the same thickness on the lower and upper parts of the field plate elements and the field plate oxide. The present embodiments are aimed at avoiding limitations of such an approach.

An embodiment of a semiconductor device includes a substrate having a background doping of a first conductivity type and including doped shielding regions of a complementary second conductivity type formed along a first substrate surface. An insulator layer is formed on the first substrate surface. A semiconductor layer is formed on the insulator layer opposite to the substrate. A first interlayer dielectric is formed on the semiconductor layer. A first metal layer that includes laterally separated first field plate elements is formed on first portions of the first interlayer dielectric. A second interlayer dielectric is formed on the first metal layer and on second portions of the first interlayer dielectric between the first field plate elements.

An embodiment of a semiconductor device includes a substrate having a background doping of a first conductivity type and including doped shielding regions of a complementary second conductivity type formed along a first substrate surface. An insulator layer is formed on the first substrate surface. A semiconductor layer is formed on the insulator layer opposite to the substrate. A first interlayer dielectric is formed on the semiconductor layer. A first metal layer that includes laterally separated first field plate elements is formed on first portions of the first interlayer dielectric. A second interlayer dielectric is formed on the first metal layer and on second portions of the first interlayer dielectric between the first field plate elements. An uppermost metal layer is formed on the second interlayer dielectric. The uppermost metal layer comprises laterally separated second field plate elements. The second interlayer dielectric vertically separates the second field plate elements from the first field plate elements. A lateral gap is formed between adjacent ones of the second field plate elements, wherein at least 50% of the lateral extension of the lateral gap is laterally overlapped by one of the first field plate elements.

Where a field plate structure of a termination region is formed from a single metal layer, a top surface of a passivation layer formed on the metal layer by using a high-density plasma includes terraces at different distances from the substrate. In contrast, in the high voltage semiconductor device according to the embodiments, the first metal layer is formed exclusively on the first portions of the first interlayer dielectric such that the second interlayer dielectric formed on the first metal layer and on second portions of the first interlayer dielectric between the first field plate elements can be planarized and allows formation of one or more further metal layers on the second interlayer dielectric. The further metal layers may be designed to shape the electric field in the termination region of the substrate and to form stable wire bond bases. The first metal layer makes it possible to define, in a single patterning process, both a lower portion of the field plate structure in the termination region and interconnection lines for electrical components formed in device portions on both sides of the termination region. The thickness of the further metal layers and the thickness of the first metal layer can be different and can be adapted independently to the respective requirements.

The invention relates to high voltage semiconductor devices having a high voltage domain and a low voltage domain. One more specific example for such a high voltage semiconductor device is a gate driver device having a high side part (as the high voltage domain) and a low side part (as the low voltage domain).

Those skilled in the art will recognize additional features and advantages by reading the following detailed description and viewing the accompanying drawings.

### BRIEF DESCRIPTION OF THE DRAWINGS

The accompanying drawings are provided for further understanding of the embodiments and form an integral part of this description. The drawings illustrate embodiments of a HV semiconductor device having active elements integrated in a HV termination structure and, together with the description, explain the principles underlying the embodiments. Further embodiments are described in the following detailed description and in the claims. Features of the various embodiments may be combined with each other.

FIG. 1 is a schematic vertical cross-sectional view of a portion of a semiconductor device with an active element integrated in a high-voltage termination structure in accordance with an embodiment having laterally separated first field plate elements formed on first portions of a first interlayer dielectric and with a second interlayer dielectric covering second portions of the first interlayer dielectric and the first field plate elements.

FIG. 2 is a schematic plan view on the field plate elements of the semiconductor device of FIG. 1 in accordance with an embodiment.

FIG. 3 is a schematic vertical cross-sectional view of a portion of a semiconductor device with an active element integrated in a high-voltage termination structure in accordance with an embodiment having second field plate elements formed on the second interlayer dielectric.

FIG. 4 is a schematic vertical cross-sectional view of a portion of a semiconductor device with an active element integrated in a high-voltage termination structure in accordance with an embodiment with an intermediate metal layer and an intermediate dielectric layer between the second interlayer dielectric and the second field plate elements.

FIG. 5 is a schematic horizontal cross-sectional view of the semiconductor device of FIG. 3 or FIG. 4 in a plane cutting shielding regions formed in a substrate in accordance with an embodiment.

FIG. 6 is a schematic plan view of the semiconductor device of FIG. 3 or FIG. 4 in accordance with an embodiment.

FIG. 7 is a schematic vertical cross-sectional view of a portion of a semiconductor device with a semiconductor diode integrated in a high-voltage termination structure in accordance with an embodiment.

FIG. 8A is a schematic plan view of a semiconductor device with a field plate structure including modified sections below active elements integrated in a high-voltage termination structure in accordance with an embodiment.

FIG. 8B shows a detail of the field plate structure of FIG. 8A in accordance with an embodiment related to modified field plate sections with lowered peak dopant concentration.

FIG. 8C shows a detail of the field plate structure of FIG. 8A in accordance with an embodiment related to modified field plate sections with narrowed width.

FIG. 9 is a schematic block diagram of a gate driver circuit with two level shift transistors for exchanging electric signals between a high side part and a low side part in accordance with an embodiment.

FIG. 10 is a schematic plan view of a semiconductor device with active elements integrated in a high-voltage termination structure in accordance with an embodiment.

FIG. 11 is a schematic plan view of a semiconductor device with active elements integrated in a high-voltage termination structure in accordance with an embodiment.

FIG. 12 is a schematic plan view of a HV semiconductor diode integrated in a high-voltage termination structure of a semiconductor device and including a compensation structure in accordance with an embodiment.

FIG. 13 is a schematic plan view of a HV semiconductor diode integrated in a high-voltage termination structure of a semiconductor device and including a compensation structure in accordance with another embodiment.

FIG. 14 is a schematic plan view of a level shift transistor integrated in a high-voltage termination structure of a semiconductor device and including a compensation structure in accordance with an embodiment.

FIG. 15A is a schematic vertical cross-sectional view of a portion of a semiconductor device with a field effect transistor integrated in a high-voltage termination structure in accordance with an embodiment, and FIG. 15B shows a magnified excerpt from FIG. 15A.

FIG. 16A is a schematic vertical cross-sectional view of a portion of a semiconductor device with a field effect transistor integrated in a high-voltage termination structure in accordance with an embodiment, and FIG. 16B shows a magnified excerpt from FIG. 16A.

### DETAILED DESCRIPTION

In the following detailed description, reference is made to the accompanying drawings which form a part of this document and in which certain embodiments of a semiconductor device with active elements integrated in a high-voltage termination structure are shown as illustrations. Structural or logical changes may be made to the illustrated embodiments without departing from the scope of the present disclosure. For example, features shown or described for one embodiment may be used on or in conjunction with other embodiments, resulting in another embodiment. The present disclosure is intended to include such modifications and variations. The embodiments are described in a manner that should not be construed as limiting the scope of the appended claims. The drawings are not to scale and are for illustrative purposes only. Corresponding elements are designated by the same reference numerals in the various drawings, unless otherwise indicated.

The terms “having”, “containing”, “including”, “comprising” and the like are open-ended, and the terms indicate the presence of certain structures, elements or features but do not preclude the presence of additional elements or features. The articles “a”, “an” and “the” include both the plural and singular, unless the context clearly indicates otherwise.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

The term “directly electrically connected” describes a permanent low-resistive ohmic connection between electrically connected elements, for example a direct contact between the concerned elements or a low-resistive connection via a metal and/or heavily doped semiconductor material.

The terms “signal-connected” and “electrically coupled” include a permanent low-resistive ohmic connection between electrically connected elements, for example a direct contact between the concerned elements or a low-resistive connection via a metal and/or heavily doped semiconductor material, but do not preclude the presence of further passive and/or active elements in the signal path between the “signal-connected” or “electrically coupled” elements. For example, the further elements may include resistors, resistive conductor lines, capacitors and/or inductors, transistors, semiconductor diodes, Schottky diodes, transformers, opto-couplers and other.

The term “power semiconductor device” refers to semiconductor devices with a high voltage blocking capability of at least 30 V, for example 48 V, 100 V, 600 V, 1.6 kV, 3.3 kV or more and with a nominal on-state current or forward current of at least 200 mA, for example 1 A, 10 A or more.

MOSFETs (metal oxide semiconductor field effect transistor) are voltage-controlled devices and include all types of IGFETs (insulated gate field effect transistors) with gate electrodes based on doped semiconductor material and/or metal and with gate dielectrics made of oxide and/or dielectric materials other than oxides.

An ohmic contact describes a non-rectifying electrical junction between two conductors, e.g., between a semiconductor material and a metal. The ohmic contact has a linear or approximately linear current-voltage (I-V) curve in the first and third quadrant of the I-V diagram as with Ohm's law.

Ranges given for physical dimensions include the boundary values. For example, a range for a parameter y from a to b reads as a≤y≤b. The same holds for ranges with one boundary value like “at most” and “at least”.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

Two adjoining doping regions in a semiconductor layer form a semiconductor junction. Two adjoining doping regions of the same conductivity type and with different dopant concentrations form a unipolar junction, e.g., an n/n+ or p/p+ junction along a boundary surface between the two doping regions.

At the unipolar junction a dopant concentration profile orthogonal to the unipolar junction may show a step or a turning point, at which the dopant concentration profile changes from being concave to convex, or vice versa. Two adjoining doping regions of complementary conductivity form a pn junction.

The Figures illustrate relative doping concentrations by indicating “−” or “+” next to the doping type “n” or “p”. For example, “n-” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

The present disclosure concerns a high voltage semiconductor device that includes a substrate having a background doping of a first conductivity type. The substrate may include doped shielding regions of a complementary second conductivity type formed along a first substrate surface. An insulator layer is formed on the first substrate surface. A semiconductor layer is formed on the insulator layer opposite to the substrate. A first interlayer dielectric is formed on the semiconductor layer. A first metal layer that may include laterally separated first field plate elements is formed on first portions of the first interlayer dielectric. A second interlayer dielectric is formed on the first metal layer and on second portions of the first interlayer dielectric between the first field plate elements.

The substrate may have a planar first substrate surface that extends in horizontal directions. A normal on the first substrate surface defines a vertical direction. The substrate, the insulator layer, the semiconductor layer, the first interlayer dielectric, the first metal layer and the second interlayer dielectric or at least portions thereof are vertically stacked one on each other along the vertical direction.

The doped shielding regions may form a doped shielding structure in the substrate. The doped shielding structure is formed in a termination region with high voltage blocking capability between a first device region and one or more further device regions. The doped shielding structure may form a frame around a first device region. The frame may be closed or have gaps. Along the perimeter of the frame, the dimensions, dopant dose and/or dopant profile of the doped shielding regions may be constant or vary.

The semiconductor layer may be formed on a planar front surface of the insulator layer. The semiconductor layer may include a plurality of laterally separated device portions, wherein lateral insulator structures may separate the device portions in the horizontal directions.

The first interlayer dielectric may be a homogenous layer or a layer stack including two or more sublayers of different composition and/or internal structure. The first interlayer dielectric may be a deposited silicon oxide layer and/or may include doped or undoped silicate glass, silicon nitride, and/or silicon oxynitride. The first interlayer dielectric covers the device portions of the semiconductor layer and the lateral insulator structures between neighboring device portions. The first interlayer dielectric may be in direct contact with the device portions of the semiconductor layer.

The first metal layer with the first field plate element or first field plate elements may be in direct contact with the first interlayer dielectric. The first metal layer may be a homogenous layer or include two or more sublayers with different compositions.

The second interlayer dielectric may be a homogenous layer or a layer stack including two or more sublayers of different composition and/or internal structure. The second interlayer dielectric may be a deposited silicon oxide layer and/or may include doped or undoped silicate glass, silicon nitride, and/or silicon oxynitride. The second interlayer dielectric covers the first metal layer with the first field plate elements and fills gaps between the first field plate elements. In the gaps between the first field plate elements, the second interlayer dielectric is directly formed on the second portions of the first interlayer dielectric. A top surface of the second interlayer dielectric may be planar, e.g., planarized by a CMP (chemical mechanical polishing) process.

The first field plate elements and the shielding regions are in a predetermined lateral position in relation to each other. The number of first field plate elements can be equal to the number of shielding regions. For some or all of the first field plate elements, the vertical projection of one first field plate element onto the first substrate surface may overlap with exactly one of the shielding regions.

The first field plate elements can be formed in the same patterning process as interconnection lines for electrical devices formed in the device portions of the semiconductor layer. The interconnections lines and the first field plate elements are formed from different sections of one deposited metal layer or metal layer stack and can be defined in the same photolithographic mask.

According to an embodiment the high voltage semiconductor device may include first field plate elements that laterally surround a first device region.

The first field plate elements form a first field plate structure that may completely surround the first device region. The first field plate structure may be completely formed in a termination region laterally separating the first device region and a second device region. The termination region is formed with a high voltage blocking capability between conductive and/or semiconducting elements formed in the first device region and conductive and/or semiconducting elements formed in the second device region.

The first device region may include first active elements operating at a first signal voltage level. The second device region may include second active elements operating at a second signal voltage level different from the first signal voltage level. A difference between the first and second signal voltage levels may be several hundred Volts or even up to 2000V.

According to an embodiment a top surface of the second interlayer dielectric opposite the first metal layer may be planar. The second interlayer dielectric may include openings extending from the top surface to the first metal layer.

Forming the second interlayer dielectric may include depositing the material(s) of the second interlayer dielectric and planarizing the deposited material(s) by CMP to obtain the planar top surface. A thickness of the second interlayer dielectric may be in a range from 250 nm to 4 μm, e.g., from 500 nm to 2 μm.

According to an embodiment the high voltage semiconductor device may further include an uppermost metal layer formed on the second interlayer dielectric.

The uppermost metal layer can be directly formed on the planar top surface of the second interlayer dielectric opposite the first metal layer. Alternatively, further layers may be formed between the second interlayer dielectric and the uppermost metal layer.

The uppermost metal layer may be a homogenous layer or include two or more sublayers with different compositions. A thickness of the uppermost metal layer is independent from a thickness of the first metal layer. For example, the uppermost metal layer and the first metal layer may have approximately the same thickness.

According to an embodiment the uppermost metal layer may include laterally separated second field plate elements. The second interlayer dielectric may vertically separate the second field plate elements from the first field plate elements.

The second field plate elements form a second field plate structure. The second field plate structure may be completely formed in the termination region. The second field plate structure may completely surround the first device region.

According to an embodiment field plate contacts may extend from the second field plate elements through openings in the second interlayer dielectric to the first field plate elements.

The field plate contacts may electrically connect each of the second field plate elements with one single first field plate element such that each first field plate element is connected to one second field plate element, and each second field plate element is connected to one first field plate element.

One first field plate element and one second field plate element form a vertically patterned field plate. A vertical cross-section of the field plate can be varied by varying the lateral widths of the first and second field plate elements, and/or by a lateral displacement between the lateral centers of the first and second field plate elements, so that the electric field distribution in the termination region can be adjusted for a desired trade-off between high voltage breakdown capability and area efficiency.

According to an embodiment the uppermost metal layer is formed directly on the second interlayer dielectric.

No further layer, in particular, no further metal layer is formed between the first metal layer and the uppermost metal layer.

According to another embodiment at least one intermediate metal layer is formed between the first metal layer and the uppermost metal layer.

One or more intermediate interlayer dielectric (s) separate the intermediate metal layer(s) from the first metal layer and/or from each other.

According to an embodiment each of the at least one intermediate metal layers may include intermediate field plate elements, wherein each intermediate field plate element may be electrically connected with one of the first field plate elements.

One first field plate element, one second field plate element and one intermediate field plate element of each intermediate metal layer can form a vertically patterned field plate. A vertical cross-section of the resulting field plate can be varied by varying the lateral widths of the first, second and intermediate field plate elements, and/or by a lateral displacement between the lateral centers of the first, second, and intermediate field plate elements, so that the electric field distribution in the termination region can be adjusted for a desired trade-off between high voltage breakdown capability and area efficiency.

According to an embodiment, a first lateral gap is formed between adjacent ones of the first field plate elements, wherein at least 50% or at least 80% of the lateral extension of the first lateral gap is laterally overlapped by one of the second field plate elements. In another embodiment, 100% (e.g. +/−5% due to tolerances) of said gap is laterally overlapped by said second field plate element while the second field plate element overlaps only one of the adjacent first field plate elements. In this case, said second field plate element overlaps one of the adjacent first field plate elements while side edges of the second field plate element and the other adjacent first field plate element are laterally aligned.

According to an embodiment, one of the second field plate elements laterally overlaps at least a portion of each first field plate element from two adjacent ones of the first field plate elements.

According to a further embodiment, the one of the second field plate elements further laterally overlaps at least 20% or at least 50% of one of the two adjacent ones of the first field plate elements.

According to an embodiment, a second lateral gap is formed between adjacent ones of the second field plate elements, wherein at least 50% of the lateral extension of the second lateral gap is laterally overlapped by one of the first field plate elements. In another embodiment, 100% (e.g. +/−5% due to tolerances) of said gap is laterally overlapped by said first field plate element while the first field plate element overlaps only one of the adjacent second field plate elements. In this case, said first field plate element overlaps one of the adjacent second field plate elements while side edges of the first field plate element and the other adjacent second field plate element are laterally aligned.

According to an embodiment, one of the first field plate elements laterally overlaps at least a portion of each second field plate element from two adjacent ones of the second field plate elements.

According to a further embodiment, the one of the first field plate elements further laterally overlaps at least 20% or at least 50% of one of the two adjacent ones of the second field plate elements.

According to an embodiment a thickness of the uppermost metal layer may be at least 1.2-fold, e.g., at least twice a thickness of the first metal layer.

In particular, the uppermost metal layer may be suitable as wire bond base. For example, the uppermost metal layer may be formed from an alloy containing aluminum Al and/or copper Cu. The thickness of the uppermost metal layer may be at most 10-fold the thickness of the first metal layer.

The second field plate elements can be formed in the same patterning process as the wire bond pads. The wire bond pads and the second field plate elements are formed from different sections of one deposited metal layer or metal layer stack and can be defined in the same photolithographic mask.

According to an embodiment the doped shielding regions may form laterally separated frames around a first device region.

Each of the first field plate elements, the second field plate elements and the shielding regions has a width along a line directly connecting the first device region and the second device region. The width of each field plate element and the width of each shielding region may be uniform along the complete perimeter of the termination region. Alternatively, the width of each shielding region may vary and depend on whether an active element, and if so, what kind of active element is formed in the semiconductor layer in the concerned section of the termination region.

Each first field plate element can be formed directly above one single of the shielding regions. The widths of the first field plate element and the associated shielding region may be different. The lateral center lines of the first field plate element and the associated shielding region may be vertically aligned to each other or may be slightly displaced against each other, wherein the lateral center lines of the first field plate elements may be inwardly or outwardly displaced with respect to the lateral center lines of the shielding regions.

Each second field plate element is formed directly above one single of the shielding regions. At least some, most or all second field plate elements are wider than the respective first field plate element in the vertical projection thereof and/or the respective shielding region in the vertical projection thereof. The lateral center lines of the second field plate element and the associated shielding region may be vertically aligned to each other or may be inwardly or outwardly displaced with respect to the first device region.

A distance between two neighboring second field plate elements can be less than a distance between the two associated first field plate elements and/or a distance between the two associated shielding regions.

According to an embodiment an active element is formed in a transition device portion of the semiconductor layer.

The transition device portion may extend from a first device region or from within the first device region on a first side of the first field plate elements to or into a second device region on a second side of the first field plate elements.

That is, the transition device portion extends from a first side of a first field plate structure, which includes the first field plate elements, to a second side of the first field plate structure.

The semiconductor layer includes one or more laterally separated first device portions in the first device region. The first device portions are formed entirely on a first side of the first field plate structure. The second device portions are formed entirely on a second side of the first field plate structure. The active element includes a main portion formed in the termination region and may further include an inner sub-portion in the first device region and/or an outer sub-portion in the second device region.

The active element may be a level shifter transistor, or a high voltage diode (Hv diode) such as a bootstrap diode or an ESD diode. The high voltage semiconductor device may include a plurality of transition device regions with more than one ESD diode, more than one bootstrap diode and/or more than one level shifter transistor.

According to an embodiment the shielding regions form laterally separated frames around a first device region. First sections of the shielding regions directly facing the transition device portion may differ from second sections not directly facing a shielding region in width, dopant dose, and/or dopant profile.

The shielding regions may form closed loops of varying width and/or varying dopant profiles. The semiconductor layer may include more than one transition device portion, wherein in each transition device portion another, different active element is formed. Opposite to each transition device portion, another section of the shielding regions can be formed. Each section of the shielding regions may have another width and/or another maximum dopant concentration.

According to an embodiment a portion of at least one of the shielding regions results from implanting dopants through a mask with parallel mask slots.

A distance between neighboring mask slots can be sufficiently small such that after implantation and annealing, a continuous shielding region without gaps is formed in the concerned substrate area below the mask slots. A common implantation process may be shared to form differently doped sections of the shielding regions.

According to an embodiment the active element may be a bootstrap diode.

According to another embodiment the active element may be a level shift transistor.

The high voltage semiconductor device may include a plurality of active elements, e.g., more than one ESD diode, more than one bootstrap diode and/or more than one level shifter transistor.

According to an embodiment the high voltage semiconductor device includes a further active element with different functionality than the active element, wherein the first field plate elements laterally overlap both active elements in a respective overlap area, and wherein the first field plate elements have a same spacing among each other in both overlap areas.

The first field plate elements can have the same dimensions and spacings to each other in the region of both active elements. In addition, the second field plate elements, any intermediate field plate elements and the doped shielding regions can have the same dimensions and spacings to each other for both active elements. The resulting vertically patterned field plates have the same effect in both active elements and provide for both active elements the same lateral field distribution along the radial direction. The same may hold for more than two active elements, e.g., for all active elements formed in the HV termination.

According to an embodiment the active element may include a compensation structure. The compensation structure may include p doped regions and n doped regions alternatingly arranged along a horizontal direction orthogonal to a current flow direction in the active element.

The compensation structure may have a superjunction configuration with dopants in the p doped regions and dopants in the n doped regions compensating each other to a high degree. Widths and dopant profiles of the p doped regions and the n doped regions are selected to meet a tradeoff between HV breakdown voltage and drive current capability and/or can be used to fine-tune the voltage blocking capability of the termination region. The p doped regions and n doped regions can be formed by low-dose implants otherwise available in the baseline process. Formation of the p doped regions may be combined with the body implants for the logic MOSFETs in the first and second device portions of the semiconductor layer.

According to an embodiment a thickness of the insulator layer may be in a range from 40 nm to 1000 nm.

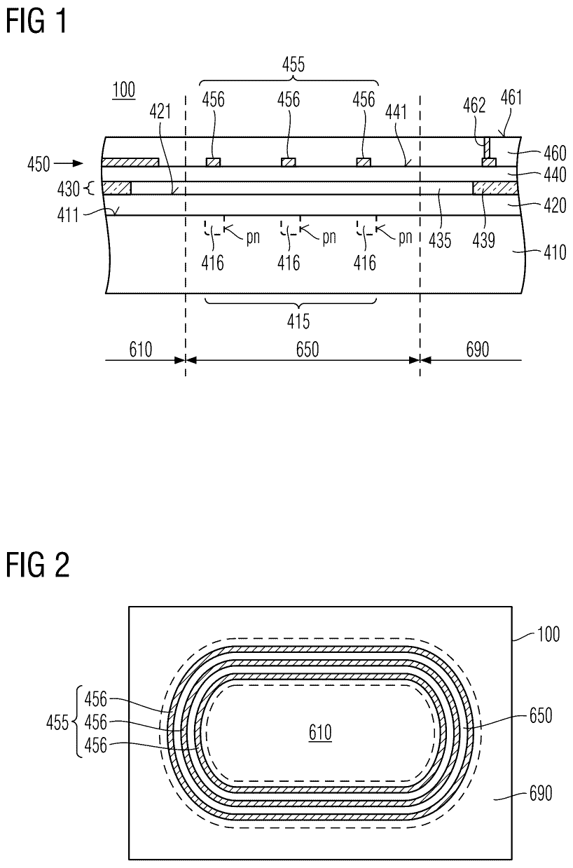

FIG. 1 shows a high voltage semiconductor device 100 that includes a first device region 610, a second device region 690 and a termination region 650 laterally separating the first device region 610 and the second device region 690.

The semiconductor device includes a substrate 410 with a planar first substrate surface 411. The first substrate surface 411 extends in horizontal (lateral) directions. A normal on the first substrate surface 411 defines a vertical direction. The substrate 410 includes a semiconductor material. The semiconductor material may be, by way of example, any group IV element semiconductor, e.g. silicon Si or germanium Ge, any group IV compound semiconductor, e.g. silicon carbide SiC or silicon germanium SiGe, or any group III/V compound semiconductor. The substrate 410 is single-crystalline and may have a uniform n type background doping. In the termination region 650, p doped shielding regions 416 extend from the first substrate surface 411 into the substrate 410. The p doped shielding regions 416 form a shielding structure 415 between the first device region 610 and the second device region 690.

An insulator layer 420 formed directly on the first substrate surface 411 separates the substrate 410 and a semiconductor layer 430 formed on a side of the insulator layer 420 opposite the substrate 410. The insulator layer 420 is a homogenous layer or a layer stack including two or more sublayers of different composition and/or internal structure (German: Gefüge). For example, the insulator layer 420 includes or consists of deposited silicon oxide and/or thermally grown silicon oxide. A thickness of the insulator layer 420 may be in a range from 40 nm to 1000 nm.

The semiconductor layer 430 is formed directly on a planar front surface 421 of the insulator layer 420. The semiconductor layer 430 includes a transition device portion 435, wherein at least a part of the transition device portion 435 is formed in the transition region 650. In the illustrated embodiment, the transition device portion 435 laterally extends into the first device region 610 and the second device portion 690. In other embodiments, the transition device portion 435 may be formed completely within the transition region 650, may extend from the transition region 650 only into the first device region 610, or may extend from the transition region 650 only into the second device region 690.

A lateral insulator structure 439 laterally separates the transition device portion 435 from other device portions of the semiconductor layer 430. The lateral insulator structure 439 fills a gap between the transition device portion 435 and the further device portions and can include local oxidation of silicon (LOCOS) structures or shallow trench isolations (STIs). A vertical extension of the lateral insulator structure 439 and a vertical extension of the transition device portion 435 may be equal.

A first interlayer dielectric 440 is formed directly on the semiconductor layer 430 on a side opposite the insulator layer 420. The first interlayer dielectric 440 may be a homogenous layer or a layer stack including two or more sublayers of different composition and/or internal structure. The first interlayer dielectric 440 may be or include a deposited silicon oxide layer and/or a doped or undoped silicate glass layer, a silicon nitride layer, and/or silicon oxynitride layer. The first interlayer dielectric 440 covers the transition device portion 435 of the semiconductor layer 430 and the lateral insulator structures 439 surrounding the transition device portion 435. The lateral insulator structures 439 may be formed from the material forming the first interlayer dielectric 440.

A first metal layer 450 is formed directly on a planar top surface 441 of the first interlayer dielectric 440 on a side opposite the semiconductor layer 430. The first metal layer 450 includes laterally separated first field plate elements 456, which are formed on first portions of the top surface 441 of the first interlayer dielectric 440. The first metal layer 450 may be a homogenous layer or may include two or more sublayers containing metals. The first metal layer 450 may include one or more elemental metal (s) such as aluminum Al, copper Cu, tungsten W, tantalum Ta or titanium Ti, a metal nitride such as titanium nitride TiN, tantalum nitride TaN, and/or a metal alloy containing at least one of aluminum Al and copper Cu. The first field plate elements 456 form a first field plate structure 455 between the first device region 610 and the second device region 690.

The first field plate structure 455 and the shielding structure 415 cooperate to provide high voltage blocking capability between the first device region 610 and the second device region 690 at high area efficiency.

For this purpose, the first field plate elements 456 and the shielding regions 416 are laterally aligned to each other, wherein each lateral edge of each first field plate element 456 has a predefined lateral distance to a corresponding lateral edge of a corresponding shielding region 416. The number of first field plate elements 456 and the number of shielding regions 416 may be equal. A vertical projection of each first field plate element 456 onto the first substrate surface 411 overlaps to some degree with one of the shielding regions 416. A width of a first field plate element 456 may be greater or smaller than a width of the corresponding shielding region 416. Alternatively, the width of a first field plate element 456 and the width of the corresponding shielding region 416 may be equal.

A second interlayer dielectric 460 is formed directly on the first metal layer 450 on a side opposite the first interlayer dielectric 440. The second interlayer dielectric 460 may be a homogenous layer or a layer stack including two or more sublayers of different composition and/or internal structure. The second interlayer dielectric 460 may consist of or include a deposited silicon oxide layer and/or may include a doped or undoped silicate glass layer, a silicon nitride layer, and/or a silicon oxynitride layer.

The second interlayer dielectric 460 covers the first field plate elements 456 and fills gaps between the first field plate elements 456. In the gaps between the first field plate elements 456, the second interlayer dielectric 460 is formed directly on second portions of the top surface 441 of the first interlayer dielectric 440 exposed by the first metal layer 450. Forming the second interlayer dielectric 460 may include depositing the material(s) of the second interlayer dielectric 460 and planarizing the deposited material(s) by chemical-mechanical polishing (CMP) to obtain a planar top surface 461. Contact vias 462 may extend from a top surface 461 of the second interlayer dielectric 460 to the first metal layer 450.

The substrate 410, the insulator layer 420, the semiconductor layer 430, the first interlayer dielectric 440, the first metal layer 450 and the second interlayer dielectric 460 are vertically stacked one on each other along the vertical direction.

The first field plate elements 456 in the termination region 650 can be formed in the same patterning process as interconnection lines that electrically connect electrical devices formed in device portions of the semiconductor layer 430 in the device regions 610, 690 of the semiconductor device 100. The interconnections lines and the first field plate elements 456 are formed from different sections of the same deposited metal layer or metal layer stack and can be defined in the same photolithographic mask.

FIG. 2 shows a first field plate structure 455 that laterally surrounds a first device region 610.

In the illustrated semiconductor device 100, the first field plate structure 455 includes three laterally separated first field plate elements 456. The first field plate structure 455 is completely formed in a termination region 650 that laterally separates the first device region 610 and a second device region 690. The termination region 650 provides a high voltage blocking capability between conductive and/or semiconducting elements formed in the first device region 610 and conductive and/or semiconducting elements formed in the second device region 690.

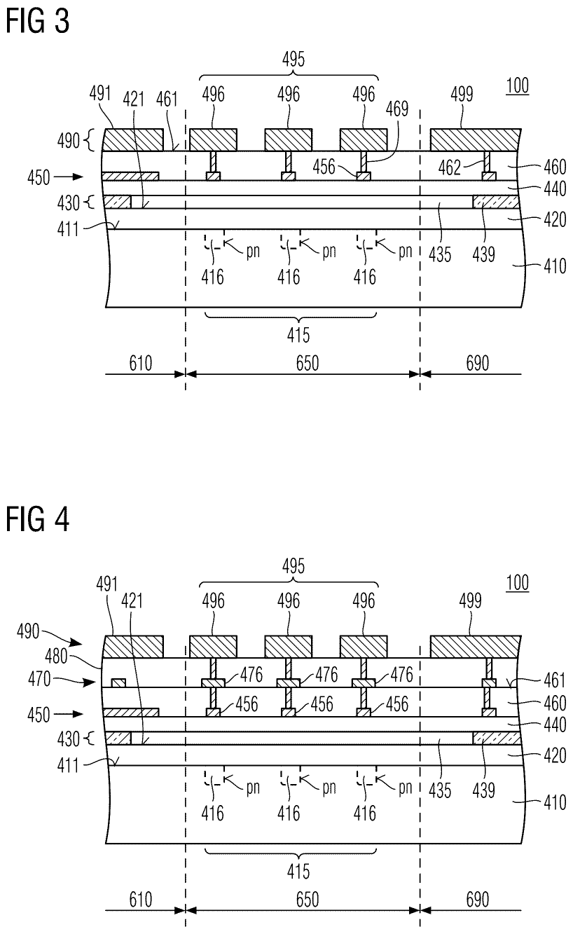

FIG. 3 shows an uppermost metal layer 490 formed directly on the planar top surface 461 of the second interlayer dielectric 460 on a side opposite the first metal layer 450. The uppermost metal layer 490 includes laterally separated second field plate elements 496, which are formed on first portions of the top surface 461 of the second interlayer dielectric 460. The uppermost metal layer 490 may include one or more elemental metal(s) such as aluminum Al, copper Cu, tungsten W, tantalum Ta or titanium Ti, a metal nitride such as titanium nitride TiN, tantalum nitride TaN, and/or a metal alloy containing at least one of aluminum Al and copper Cu. The second field plate elements 496 form a second field plate structure 495 between the first device region 610 and the second device region 690.

The second field plate structure 495 is completely formed in the termination region 650 and may surround the first device region 610 completely.

Field plate contacts 469 extend from the second field plate elements 496 through openings in the second interlayer dielectric 460 to the first field plate elements 456.

The field plate contacts 469 may electrically connect each of the second field plate elements 496 with a first field plate element 456, e.g., with one single first field plate element 456, such that each second field plate element 496 is connected to at least one first field plate element 456, and each first field plate element 456 is connected to one second field plate element 496.

A group of first and second field plate elements 456, 496, e.g., one first field plate element 456 and one second field plate element 496 form a vertically patterned field plate. A vertical cross-section of the field plate can be varied by varying the lateral widths of the first and second field plate elements 456, 496 and/or by a lateral displacement between the lateral centers of the first and second field plate elements 456, 496 so that the electric field distribution in the termination region 650 can be adjusted for a desired trade-off between high voltage breakdown capability and area efficiency.

In the semiconductor device 100 of FIG. 3, no further metal layer is formed between the first metal layer 450 and the uppermost metal layer 490.

In the semiconductor device 100 illustrated in FIG. 4, one intermediate metal layer 470 and one intermediate interlayer dielectric 480 are formed between the first metal layer 450 and the uppermost metal layer 490.

The intermediate metal layer 470 includes laterally separated intermediate field plate elements 476. Each intermediate field plate element 476 is electrically connected with at least one of the first field plate elements 456 and with at least one of the second field plate elements 496.

In the illustrated embodiment, each intermediate field plate element 476 is electrically connected with one of the first field plate elements 456 and with one of the second field plate elements 496, wherein one first field plate element 456, one intermediate field plate element 476 electrically connected with the first field plate element 456, and one second field plate element 496 electrically connected with the intermediate field plate element 476 form a vertically patterned field plate. A vertical cross-section of the resulting field plate can be varied by varying the lateral widths of the first, second and intermediate field plate elements 456, 496, 476 and/or by a lateral displacement between the lateral centers of the first, second, and intermediate field plate elements 456, 496, 476 so that the electric field distribution in the termination region 650 can be adjusted for a desired trade-off between high voltage breakdown capability and area efficiency.

The thickness of the intermediate metal layer 470 and the thickness of the first metal layer 450 may be equal or may deviate from a mean value of both by at least 20% of the mean value. The thickness of the intermediate metal layer 470 and the thickness of the uppermost metal layer 450 may be equal or may deviate from a mean value of both by at least 20% of the mean value.

FIG. 3 and FIG. 4 show a thickness of the uppermost metal layer 490 that exceeds a thickness of the first metal layer 450 by a factor of at least two.

The uppermost metal layer 490 and the second interlayer dielectric 460 of FIG. 3 or the uppermost intermediate interlayer dielectric 480 of FIG. 4 may be sufficiently thick to serve as wire bond base. For example, the uppermost metal layer 490 may be formed from an alloy containing at least aluminum Al and copper Cu, and a thickness of the second interlayer dielectric 460 of FIG. 3 or the intermediate interlayer dielectric 480 of FIG. 4 is in a range from 500 nm to 2 μm.

The second field plate elements 496 can be formed in the same patterning process as wire bond pads 491, 499 formed in the first and second device regions 610, 690. The wire bond pads 491, 499 and the second field plate elements 496 are formed from different sections of one deposited metal layer or metal layer stack and can be defined in the same photolithographic mask.

Where in the semiconductor device 100 illustrated in FIG. 4 one intermediate metal layer 470 and one intermediate interlayer dielectric 480 are formed between the first metal layer 450 and the uppermost metal layer 490, other embodiments may provide two or more intermediate metal layers 470 and intermediate interlayer dielectrics 480, wherein each pair of two vertically neighboring intermediate metal layers 470 is separated by one of the additional intermediate interlayer dielectrics 480.

FIG. 5 shows a semiconductor device 100 with a doped shielding structure 415 including four doped shielding regions 416 that form laterally separated frames around a first device region 610. The shielding regions 416 have the same width or approximately the same width. A distance between neighboring shielding regions 416 decreases with increasing distance to the first device region 610

The doped shielding structure 415 forms a closed multi-part frame around the first device region 610. In the illustrated embodiment, the dimensions and/or dopant concentration of the doped shielding regions 416 are constant along the perimeter of the frame. According to other embodiments, the dimensions and/or dopant concentration of the doped shielding regions 416 may vary along the perimeter of the frame.

The illustration of doped regions in the first and second device regions is simplified. Each of the first and second device regions may include one or more p doped regions.

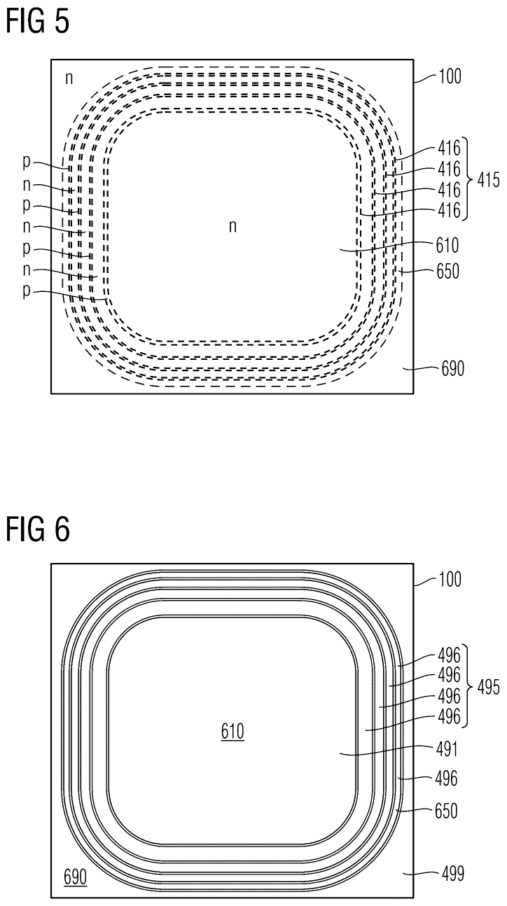

FIG. 6 shows a semiconductor device 100 with a second field plate structure 495 including four second field plate elements 496 that form laterally separated frames around a first device region 610. A width of the second field plate elements 496 may decrease with increasing distance to the first device region 610. The distances between neighboring second field plate elements 496 may be equal. The second field plate structure 495 forms a closed multi-part frame around the first device region 610. The second field plate structure 495 of FIG. 6 may be combined with the doped shielding structure 415 of FIG. 5, wherein each of the second field plate elements 496 of FIG. 6 laterally overlaps with one of the doped shielding regions 416 of FIG. 5.

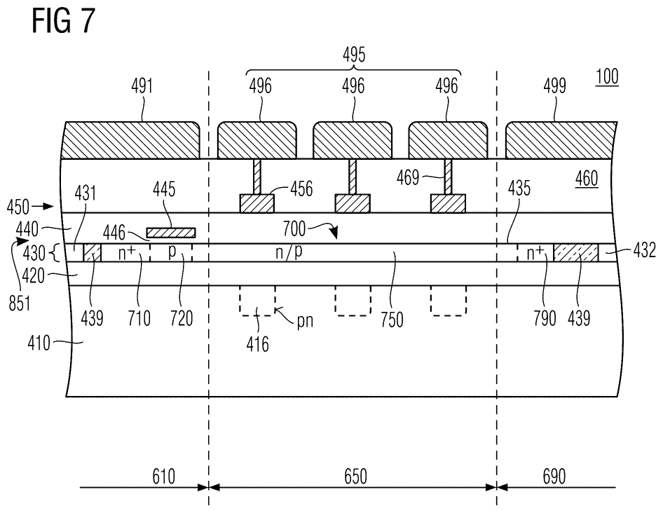

In FIG. 7, each of the first field plate elements 456 of a semiconductor device 100 is formed directly above one single of the shielding regions 416. The lateral center lines of the first field plate element 456 and the associated shielding region 416 are vertically aligned to each other. Each second field plate element 496 is formed directly above one single of the first field plate elements 456. All second field plate elements 496 are wider than the respective first field plate element 456 in the vertical projection thereof and the respective shielding region 416 in the vertical projection thereof. The lateral center lines of the second field plate element 496 and the associated shielding region 416 are vertically aligned to each other. A distance between two neighboring second field plate elements 496 is less than distances between the two associated first field plate elements 456 and between the two associated shielding regions 416.

A semiconductor layer 430 of the semiconductor device 100 includes a transition device portion 435 that extends from within the first device region 610 on a first side of the second field plate elements 496 into a second device region 690 on a second side of the second field plate elements 496. That is, the transition device portion 435 extends from a first side of a second field plate structure 495, which includes the second field plate elements 496, to a second side of the second field plate structure 495.

In addition, the semiconductor layer 430 includes one or more laterally separated first device portions 431 in the first device region 610 and one or more laterally separated second device portions 432 in the second device region 690. The first device portions 431 are formed entirely on a first side of the first field plate structure 455. The second device portions 432 are formed entirely on a second side of the first field plate structure 455.

An active element 700 formed in the transition device portion 435 includes a first portion formed in the first device region 610, a second portion formed in the second device region 690, and a third portion formed in the termination region 650. In the illustrated embodiment, the active element 700 is a level shift transistor 851.

The level shift transistor 851 is an n channel field effect transistor including a heavily n+ doped source region 710 formed at an end of the transition device portion 435 oriented to the first device region 610, and a heavily n+ doped drain region 790 formed at an end of the transition device portion 435 oriented to the second device region 690. The source region 710 and a p doped body region 720 form a vertical pn junction. A drift structure 750 connects the body region 720 and the drain region 790. The drift structure 750 may be weakly and homogeneously n doped. Alternatively, the drift structure 750 may include a superjunction structure. The superjunction structure includes a regular pattern of p doped stripes and n doped stripes alternating along a direction orthogonal to the cross-sectional plane. The p doped stripes and the body region 720 form vertical unipolar junctions. The n doped stripes and the body region 720 form vertical pn junctions. The p doped stripes and the drain region 790 may be separated by n doped zones. The n doped stripes and the drain region 790 form vertical unipolar junctions. A gate electrode 445 is formed in a portion of the first interlayer dielectric 440 above the body region 720. A gate dielectric 446 separates the gate electrode 445 and the transition device region 435.

In FIG. 7 the drift structure 750 is formed in the termination region 650, the source region 710 is formed in the first device region 610 and the drain region 790 is formed in the second device region 690.

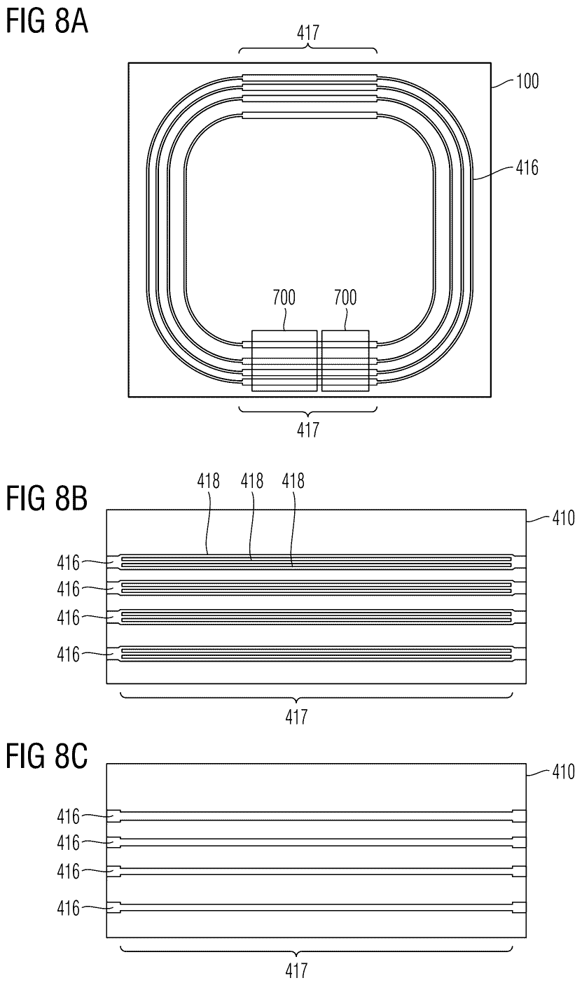

FIG. 8A to 8C show semiconductor devices 100 that include shielding regions 416 forming laterally separated frames around a first device region 610. The width in a portion of each shielding region 416 depends on whether an active element and, if so, what type of active element is formed in the vertical projection of the concerned portion of the shielding region 416. Each shielding region 416 forms a closed loop of varying width and/or varying dopant profile.

In FIG. 8A each shielding region 416 includes two modified sections 417. The modified sections 417 are formed in straight portions of the shielding regions 416. Each modified section 417 faces a transition device portion (not illustrated). The modified sections 417 may differ from unmodified sections in width and/or dopant dose.

The modified sections 417 may be formed by implanting dopants through a mask with parallel mask slots.

FIG. 8A further shows two active elements 700 of different functionalities formed in transition device regions in a portion of the termination region including the modified sections 417.

The modified sections 417 laterally overlap both active elements 700 without further modification of the lateral dimensions, the doping and the spacings between the modified sections 417. Accordingly, first field plate elements, second field plate elements, and all intermediate field plate elements can laterally overlap both active elements 700 without modification of the lateral dimensions and the lateral spacings between the modified sections 417 so that the resulting vertically patterned field plates have the same effect in both active elements 700 and provide for both active elements 700 the same lateral field distribution along the radial direction.

The same may hold for more than two active elements, e.g., for all active elements formed in the HV termination.

FIG. 8B shows a top view of a portion of a substrate 410 after implanting dopants for forming the shielding regions 416. For each shielding region 416, the implant mask includes a frame-shaped mask opening. The frame-shaped mask opening has one stripe-shaped mask opening for each unmodified section. For forming a modified section 417, the frame-shaped mask opening fans out into a plurality of parallel, stripe-shaped mask openings (mask slots) separated by mask fins.

Accordingly, the implant process forms precursor shielding regions including a plurality of parallel implant stripes 418 where the modified sections 417 are to be formed. A heat treatment diffuses the dopants contained in the implant stripes 418 to form laterally contiguous modified sections 417 with a greater width than the unmodified sections.

A total width of the fanned mask openings in the modified sections and the width of the mask opening in the unmodified sections may be the same, such that the modified sections 417 and the unmodified sections of a shielding region 416 have a same dopant dose per unit length along the circumferential direction and differ only in the lateral distribution of the dopant dose across the circumferential direction.

FIG. 8C shows modified sections 417 with a smaller width across the circumferential direction than the unmodified sections of the shielding regions 416.

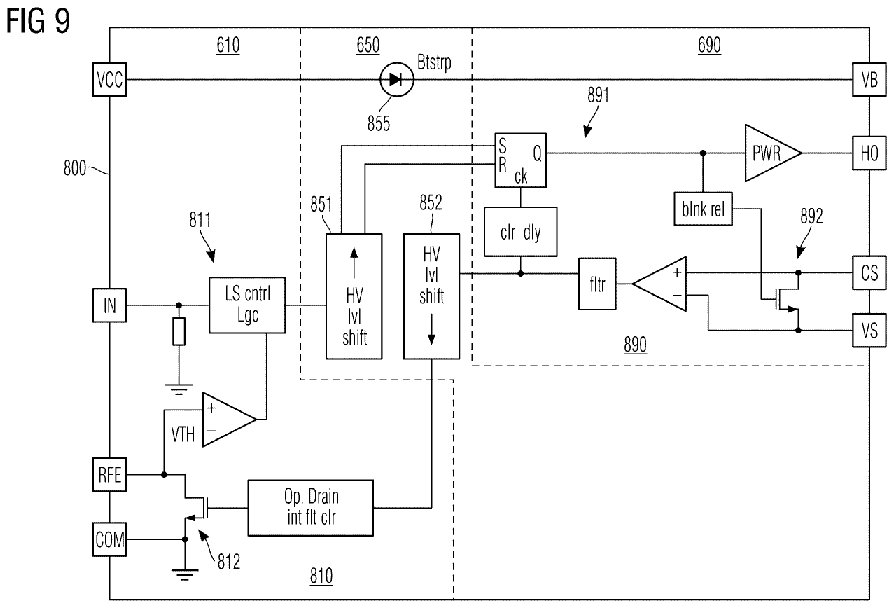

FIG. 9 shows a block diagram of a gate driver circuit 800 as an example for a semiconductor device having active elements integrated in a high voltage termination between a high voltage domain and a low voltage domain.

A CMOS part 810 of the gate driver circuit 800 forms a signal interface to standard CMOS devices. The CMOS part 810 includes inter alia a low side control logic 811 for passing an active gate input signal to a first level shift transistor 851 as long as no error condition is fulfilled. The first level shift transistor 851 is an n channel field effect transistor. The CMOS part 810 further includes an error output logic 812 for outputting an error signal received from a second level shift transistor 852. The second level shift transistor 852 is a p channel field effect transistor. The CMOS part 810 represents a low voltage domain with signal voltage levels below 5V.

A HV part 890 of the gate driver circuit 800 forms a signal interface to a power semiconductor switch. The HV part 890 may include inter alia a high side driver logic 891 for controlling an active gate input signal received from the first level shift transistor 851. The HV part 890 may further include an error detection logic 892 for outputting an error signal to the second level shift transistor 852 when a fault condition is detected. The HV part 890 represents a high voltage domain with signal voltage levels above 15V.

A bootstrap diode 855 periodically charges a capacitor connected to a VB terminal of the gate driver circuit 800 to obtain the supply voltage for the HV part 890.

The first level shift transistor 851 and the second level shift transistor 852 are parts of signal paths that exchange electric signals between the HV part 890 and the CMOS part 810.

The first level shift transistor 851, the second level shift transistor 852 and the bootstrap diode 855 may be an active element formed in the transition device portions 435 of any of the preceding illustration.

The transition device portions 435 are formed mainly in a termination region 650 between a first device region 610 and a second device region 690 as described with reference to any of the preceding illustrations. In the illustrated gate driver circuit 800, the CMOS part 810 is formed in the first device region 610 and the HV part 890 is formed in the second device region 690. According to a non-illustrated embodiment, the HV part 890 is formed in the device region 610 and the CMOS part 810 is formed in the second device region 690.

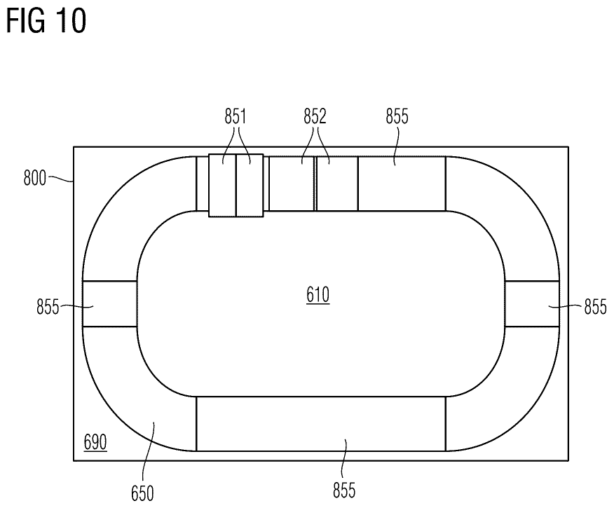

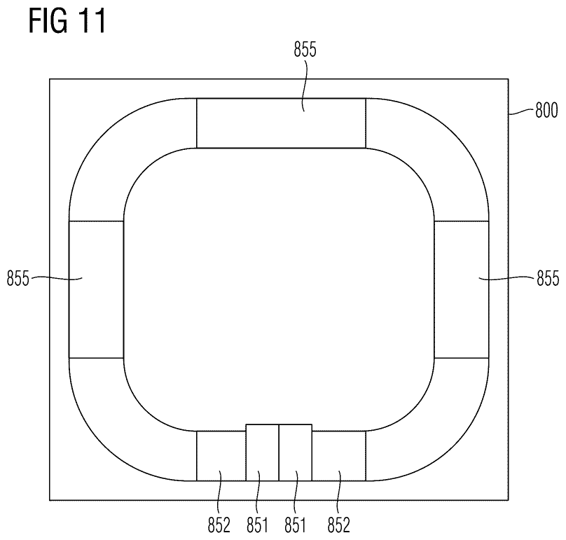

FIG. 10 and FIG. 11 show the arrangement of various active elements integrated in a termination region 650 between a first device region 610 and a second device region 690 of a gate driver circuit 800. The termination region 650 includes four straight sections and four quarter circle sections, wherein each quarter circle section connects two neighboring straight sections.

In FIG. 10 the termination region 650 includes two long straight sections and two short straight sections. In each of the four straight sections, a part of a bootstrap diode 855 is formed. In one of the long straight sections the first level shift transistor 851 and the second level shift transistor 852 are formed side-by-side.

In FIG. 11 the termination region 650 includes four straight sections of equal length. In each of three of the four straight sections, a part of a bootstrap diode 855 is formed. In the fourth straight section, the first level shift transistor 851 and the second level shift transistor 852 are formed, wherein two equal-sized parts of the second level shift transistor 852 are formed on opposite sides of the first level shift transistor 851.

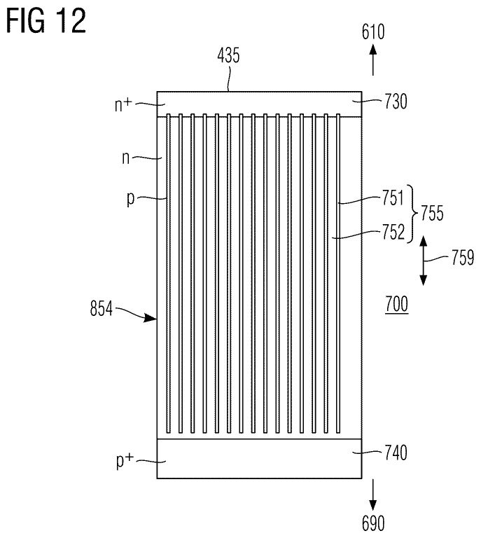

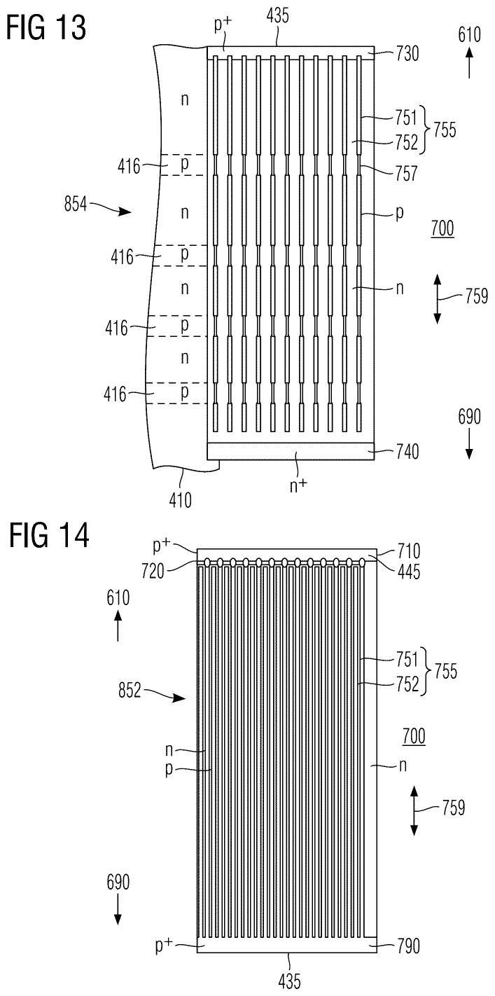

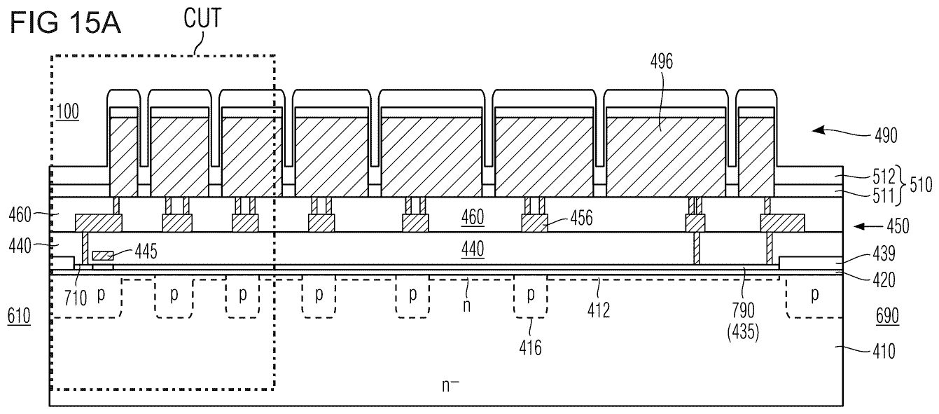

FIG. 12, FIG. 13 and FIG. 14 illustrate active elements 700 with compensation structures 755. Each active element 700 is formed in a transition device portions 435 of a semiconductor layer, wherein each transition device portions 435 is mainly formed in a termination region between a first device region 610 and a second device region 690. Arrows indicate a current flow direction 759 in an on-state or forward conductive state of the active element 700.

Each compensation structure 755 includes p doped regions 751 and n doped regions 752 alternatingly arranged along a horizontal direction orthogonal to the current flow direction 759 in the active element 700. The compensation structure 755 has a superjunction configuration with the dopants in the p doped regions 751 and n doped regions 752 compensating each other to a high degree. Widths and dopant profiles of the p doped regions 751 and the n doped regions 752 are selected to meet a tradeoff between HV breakdown voltage and drive current capability and/or can be used to fine-tune the static voltage blocking capability of the termination region 650 and the dynamic blocking stability during switching of unipolar devices like a level shift transistor. The p doped regions 751 and n doped regions 752 can be formed by low-dose implants otherwise available in the baseline process. For example, formation of the p doped regions 751 may be combined with the body implants for the logic MOSFETs in the first and second device portions 610, 690.

In FIG. 12 and FIG. 13, the active element 700 is a HV diode 854, e.g., a bootstrap diode including a heavily p+ doped anode region 730 at an end of the transition device region 435 oriented to the first device region 610 and a heavily n+ doped cathode region 740 at an end of the transition device region 435 oriented to the second device region 690. The p doped regions 751 and the n doped regions 752 are stripe-shaped with longitudinal axes parallel to the current flow direction 759.

In FIG. 12 the p doped regions 751 have a uniform lateral width along the complete length and the n doped regions 752 have a uniform lateral width along the complete length.

In FIG. 13 the width of the p doped regions 751 changes along the current flow direction 759 between a first width and a second width. The width of a section of a p doped region 751 depends on whether a shielding region 416 is formed in a vertical projection of the section. For example, sections of the p doped regions 751 in the vertical projection of a shielding region 416 have the first width and sections of the p doped regions 751 outside the vertical projection of a shielding region 416 have the second width. The first width may be narrower or wider than the second width.

In FIG. 14 the active element 700 is a p channel field effect transistor like the second level shift transistor 852 in FIG. 9. The second level shift transistor 852 includes a heavily p+ doped source region 710 at an end of the transition device region 435 oriented to the first device region 610 and a heavily p+ doped drain region 790 at an end of the transition device region 435 oriented to the second device region 690. The source region 710 and an n doped body region 720 form a pn junction. A drift structure between the body region 720 and the drain region 790 includes a compensation structure 755 with a superjunction configuration including a regular pattern of stripe-shaped p doped regions 751 and stripe-shaped n doped regions 752. The n doped regions 752 and the body region 720 form vertical unipolar junctions. The p doped regions 751 and the body region 720 form pn junctions. The n doped regions 752 and the drain region 790 may be separated by a p doped zone. The p doped regions 751 and the drain region 790 form vertical unipolar junctions. A gate electrode 445 is formed in a portion of the first interlayer dielectric above the body region 720.

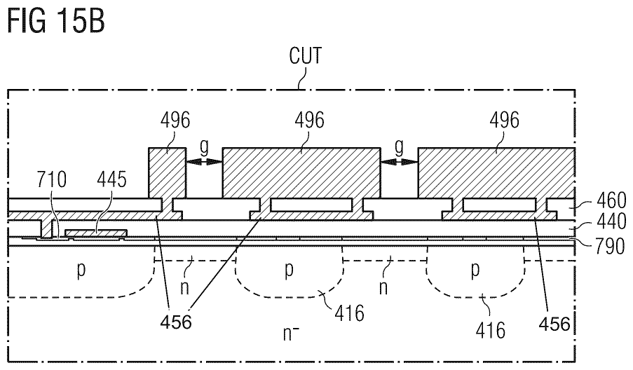

The semiconductor device 100 in FIG. 15A includes a level shift transistor formed in a transition device portion 435 of a semiconductor layer 420 that is separated from a substrate 410 by an insulator layer 420. In addition to a shielding structure 415 with p doped shielding regions 416, an n doped surface layer 412 is formed in the substrate 410 along the first substrate surface 411. FIG. 15B shows a magnified excerpt from FIG. 15A, marked with “CUT”.

A passivation layer 510 covering at least partly the uppermost metal layer 490 includes a first sub-layer 511 formed at least on exposed portions of the second interlayer dielectric 460 and a second sub-layer 512 formed on the first sub-layer 512 and, if applicable, on the uppermost metal layer 490. A second field plate element 496 oriented to the first device region 610 is electrically connected with the source region 710 of the level shift transistor. A second field plate element 496 oriented to the second device region 690 is electrically connected with the drain region 790 of the level shift transistor.

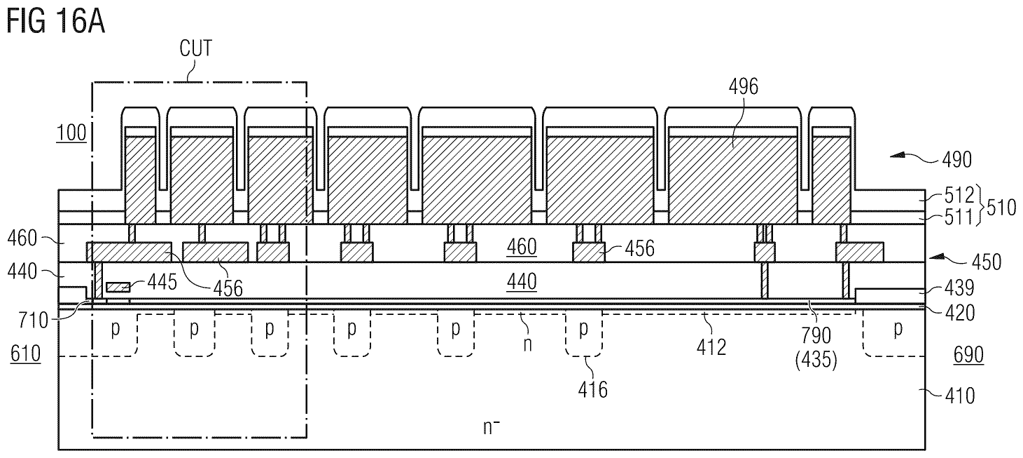

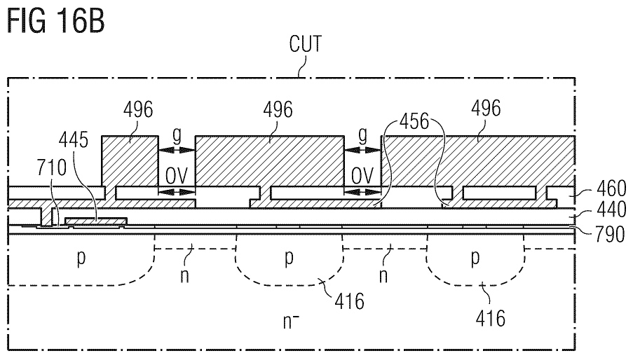

FIG. 16A shows a similar device to FIG. 15A. FIG. 16B shows a magnified excerpt from FIG. 16A, marked with “CUT”. The main difference in the design of the field plates. In FIGS. 15A and 15B, each first field plate element 456 overlaps with just one second field plate element 496.

In FIGS. 16A and 16B, a lateral gap g is formed between adjacent ones of the second field plate elements 496, wherein at least 50% of the lateral extension of the lateral gap g is laterally overlapped by one of the first field plate elements 456. The overlap between the gap g and the first field plate elements 456 is marked as 0V in FIG. 16B. According to FIGS. 16A and 16B, roughly 100% of said gap g is laterally overlapped by said first field plate element 456 while the first field plate element 456 overlaps only one of the adjacent second field plate elements 496. Therefore, said first field plate element 456 overlaps one of the adjacent second field plate elements 496 while side edges of the first field plate element 456 and the other adjacent second field plate element 496 are laterally aligned. Furthermore, the one of the first field plate elements 456 further laterally overlaps at least 20% or at least 50% of one of the two adjacent ones of the second field plate elements 496.

Analogously, another first lateral gap (not depicted) is formed between adjacent ones of the first field plate elements 456 and at least 50% or at least 80% of the lateral extension of the first lateral gap is laterally overlapped by one of the second field plate elements 496. Again, in this embodiment, the overlapping is at roughly 100%. The one of the second field plate elements 496 further laterally overlaps at least 20% or at least 50% of one of the two adjacent ones of the first field plate elements 456.

What is claimed is:

1. A high voltage semiconductor device, comprising:
a substrate having a background doping of a first conductivity type and comprising doped shielding regions of a complementary second conductivity type formed along a first substrate surface;
an insulator layer formed on the first substrate surface;
a semiconductor layer formed on the insulator layer opposite to the substrate;
a first interlayer dielectric formed on the semiconductor layer;
a first metal layer comprising laterally separated first field plate elements formed on first portions of the first interlayer dielectric in a termination region; and
a second interlayer dielectric formed on the first metal layer and on second portions of the first interlayer dielectric between the first field plate elements.

2. The high voltage semiconductor device of claim 1, wherein the first field plate elements laterally surround a first device region.

3. The high voltage semiconductor device of claim 1, wherein a top surface of the second interlayer dielectric opposite the first metal layer is planar, and wherein the second interlayer dielectric comprises openings extending from the top surface.

4. The high voltage semiconductor device of claim 1, further comprising:
an uppermost metal layer formed on the second interlayer dielectric.

5. The high voltage semiconductor device of claim 4, wherein the uppermost metal layer comprises laterally separated second field plate elements, and wherein the second interlayer dielectric vertically separates the second field plate elements from the first field plate elements.

6. The high voltage semiconductor device of claim 5, wherein a lateral gap is formed between adjacent ones of the first field plate elements, and wherein at least 50% or at least 80% of a lateral extension of the first lateral gap is laterally overlapped by one of the second field plate elements.

7. The high voltage semiconductor device of claim 6, wherein the one of the first field plate elements further laterally overlaps at least 20% or at least 50% of one of the two adjacent ones of the second field plate elements.

8. The high voltage semiconductor device of claim 5, wherein a lateral gap is formed between adjacent ones of the second field plate elements, and wherein at least 50% of a lateral extension of the lateral gap is laterally overlapped by one of the first field plate elements.

9. The high voltage semiconductor device of claim 8, wherein the one of the first field plate elements further laterally overlaps at least 20% or at least 50% of one of the two adjacent ones of the second field plate elements.

10. The high voltage semiconductor device of claim 5, wherein one of the first field plate elements laterally overlaps at least a portion of each second field plate element from two adjacent ones of the second field plate elements.

11. The high voltage semiconductor device of claim 5, further comprising:
field plate contacts extending from the second field plate elements through openings in the second interlayer dielectric to the first field plate elements.

12. The high voltage semiconductor device of claim 4, wherein the uppermost metal layer is formed directly on the second interlayer dielectric.

13. The high voltage semiconductor device of claim 4, further comprising:
at least one intermediate metal layer formed between the first metal layer and the uppermost metal layer.

14. The high voltage semiconductor device of claim 13, wherein each of the at least one intermediate metal layer comprises intermediate field plate elements, and wherein each intermediate field plate element is electrically connected with one of the first field plate elements.

15. The high voltage semiconductor device of claim 4, wherein a thickness of the uppermost metal layer is at least 1.2-fold a thickness of the first metal layer.

16. The high voltage semiconductor device of claim 1, wherein the doped shielding regions form laterally separated frames around a first device region.

17. The high voltage semiconductor device of claim 1, further comprising:
an active element formed in a transition device portion of the semiconductor layer,
wherein the transition device portion extends from a first device region on a first side of the first field plate elements into a second device region on a second side of the first field plate elements.

18. The high voltage semiconductor device of claim 17, wherein the shielding regions form laterally separated frames around a first device region, and wherein modified sections of the shielding regions facing the transition device portion differ from second sections in width and/or dopant concentration.

19. The high voltage semiconductor device of claim 18, wherein a portion of at least one of the shielding regions results from implanting dopants through a mask with parallel mask slots.

20. The high voltage semiconductor device of claim 17, wherein the active element is a bootstrap diode.

21. The high voltage semiconductor device of claim 17, wherein the active element is a level shift transistor.

22. The high voltage semiconductor device of claim 17, further comprising:
a further active element with different functionality than the active element,
wherein the first field plate elements laterally overlap both active elements in a respective overlap area, the first field plate elements having a same spacing among each other in both overlap areas.

23. The high voltage semiconductor device of claim 17, wherein the active element comprises a compensation structure, and wherein the compensation structure comprises p doped regions and n doped regions alternatingly arranged along a horizontal direction orthogonal to a current flow direction in the active element.

24. The high voltage semiconductor device of claim 1, wherein a thickness of the insulator layer is in a range of 40 nm to 1000 nm.

25. A high voltage semiconductor device, comprising:
a substrate having a background doping of a first conductivity type and comprising doped shielding regions of a complementary second conductivity type formed along a first substrate surface;
an insulator layer formed on the first substrate surface;
a semiconductor layer formed on the insulator layer opposite to the substrate;
a first interlayer dielectric formed on the semiconductor layer;
a first metal layer comprising laterally separated first field plate elements formed on first portions of the first interlayer dielectric in a termination region;
a second interlayer dielectric formed on the first metal layer and on second portions of the first interlayer dielectric between the first field plate elements; and
an uppermost metal layer formed on the second interlayer dielectric,
wherein the uppermost metal layer comprises laterally separated second field plate elements,
wherein the second interlayer dielectric vertically separates the second field plate elements from the first field plate elements,
wherein a lateral gap is formed between adjacent ones of the second field plate elements,
wherein at least 50% of a lateral extension of the lateral gap is laterally overlapped by one of the first field plate elements.
